(19) United States
(12) Patent Application Publication
(10) Pub. No.: US 2005/0148120 A1
(43) Pub. Date: Jul. 7, 2005

(54) Polycide gate stucture and manufacturing method thereof

(75) Inventor: Han-Hsing Liu, Hsinchu (TW)

Correspondence Address: SILICON VALLEY PATENT GROUP LLP, 2350 MISSION COLLEGE BOULEVARD, SUITE 360, SANTA CLARA, CA, 95054, US

(73) Assignee: Winbond Electronics Corporation, Hsinchu (TW)

(21) Appl. No.: 10/748,828

(22) Filed: Dec. 29, 2003

(51) Int. Cl. H01L 21/335; H01L 21/44; H01L 21/8232

(52) U.S. Cl. 438/142

(57) ABSTRACT

A polycide gate structure and the manufacturing method thereof are provided. The manufacturing method includes the following steps of: (a) providing a substrate; (b) forming a polysilicon layer and a silicide layer upon the substrate separately; (c) removing a part of the silicide layer for defining a silicide structure having a side wall; (d) forming a protecting structure covering the side wall of the silicide structure; (e) removing the polysilicon layer not covered by the silicide structure and the protecting structure for obtaining a polysilicon structure having laterals; and (f) oxidating the polysilicon structure for forming an insulating structure on laterals of the polysilicon structure.

### FIELD OF THE INVENTION

This invention relates to a semiconductor structure and a manufacturing method thereof and more particularly to a polycide gate structure and a manufacturing method thereof, which could be applied to complementary metal oxide semiconductor (CMOS) transistors.

### BACKGROUND OF THE INVENTION

As the amazing progress in the technology of semiconductor process in these years, it promotes the prosperous development in computers, communication and networking industries. And the basic element of this progress based on the continuous decrement in complementary metal oxide semiconductor (CMOS) transistor size. Since the small device can improve the transition speed and also decrease the power dissipation thereof, the integration of devices and functions, such as data storage, logic operations and signal processing are enhanced. The complementary metal oxide semiconductor (CMOS) transistor has the advantages of high integration and low power dissipation, so it becomes the mostly used, researched and developed semiconductor device.

In the deep sub-micron technology of IC manufacturing process, the wire width, contact area and the conjunction depth are decreasing for efficiently improving the device quality, the decrements of the resistance, signal transmission delay introduced by an intrinsic resistor and capacitor (RC) and the device's gate intrinsic resistor become very important. And this is the reason why the polycide gate structure is developed to replace the previous polysilicon gate structure. Please refer to FIG. 1. The manufacturing process is to produce a tungsten suicide (WSiₓ) layer 2 upon a polysilicon layer 1. The application of tungsten silicide (WSiₓ) in semiconductor manufacturing processes becomes more and more popular especially in the use of being the gate conduction layer of metal oxide semiconductor (MOS) because of the advantages of high melting point, stability and low resistivity.

It should be noted that the polycide layer 3 is composed of two different materials of polysilicon layer 1 and tungsten silicide (WSiₓ) layer 2. The process includes two steps for etching single material separately because the etching rates of single plasma in both two materials are inconsistent. Firstly, at the first stage, the tungsten silicide (WSiₓ) layer 2 of the polycide layer 3 is etched. Then, at the second stage, the polysilicon layer 1 is etched after the etching of tungsten silicide (WSiₓ) layer 2. It will cause environmental pollution because tungsten silicide (WSiₓ) layer 2 is easy to be oxidized at high temperature and the oxide of tungsten is easy to evaporate. Generally, the plasma etching could be passably kept in the condition under 400° C. When the etching of polysilicon layer 1 is proceeded at the second stage, it needs a higher etching rate for thoroughly removing the polycide layer 3 exposed under the plasma. The temperature will be continuously increased for raising the etching rate, so tungsten silicide (WSiₓ) 2 will be oxidized caused by the excessive high temperature. Therefore, it will result in evaporable pollutant and will easily cause the leakage current because the oxide of tungsten covering on the silicon layer will increase the attach range with silicon dioxide layer 4.

From the above description, it is known that how to develop a polycide gate structure and manufacturing method with the advantages of resolving the problem of pollutant oxide produced by the tungsten layer at high temperature has become a major problem waited to be solved. In order to overcome the drawbacks in the prior art, a polycide gate structure and manufacturing method thereof are provided. The particular design in the present invention not only solves the problem described above, but also prevents the production of tungsten oxide pollutant. Thus, the invention has the utility for the industry.

### SUMMARY OF THE INVENTION

It is an object of the present invention to provide a semiconductor manufacturing method and more particularly to the manufacturing method of a polycide gate which could be applied to complementary metal oxide semiconductor (CMOS) transistors. The manufacturing method of the present invention could solve the problem of the pollutant oxide produced by the tungsten layer at high temperature and therefore conforms to industrial environmental consciousness. Furthermore, because the present invention prevents the production of tungsten oxide pollutant it could avoid the leakage current by the contact of tungsten oxide pollutant and silicon layer.

In accordance with an aspect of the present invention, a manufacturing method of a polycide gate is provided. The manufacturing method includes the following steps of providing a substrate, forming a polysilicon layer and a silicide layer upon the substrate separately, removing a part of the silicide layer for defining a silicide structure having a wall, forming a protecting structure covering the side wall of the silicide structure, removing the polysilicon layer not covered by the silicide structure and the protecting structure for obtaining a polysilicon structure having laterals, and oxidizing the polysilicon structure for forming an insulating structure on laterals of the polysilicon structure.

Preferably, the substrate includes an insulating layer.

Preferably, the insulating layer is silicon dioxide (SiO₂).

Preferably, the silicide layer on the polysilicon includes a barrier, a tungsten layer and a silicon nitride (SiNₓ) layer in sequence.

Preferably, the barrier is titanium nitride.

Preferably, the suicide structure is defined by an anisotropic dry etcher.

Preferably, the protecting layer is formed by chemical vapor deposition (CVD).

Preferably, the protecting layer has a thickness ranged from 50 to 500 A.

Preferably, the protecting layer is silicon nitride (SiNₓ).

Preferably, the protecting structure is defined via an anisotropic dry etcher.

Preferably, the polysilicon structure is defined via an anisotropic dry etcher.

Preferably, the insulating structure is formed via a dry oxidation.

In accordance with an aspect of the present invention, a manufacturing method of the protecting structure covering the wall of the silicide structure is provided. The manufacturing method includes providing a substrate, forming a polysilicon layer and a silicide layer upon the substrate, removing a part of the silicide layer for defining a silicide structure having a side wall, forming a protecting layer upon the polysilicon layer and covering the suicide structure, removing a contact crosspiece between the protecting layer and the polysilicon layer and between the protecting layer and the suicide structure to form a protecting structure, removing the polysilicon layer not covered by the silicide structure and the protecting structure for obtaining a polysilicon structure having laterals, and oxidizing the polysilicon structure for forming an insulating structure on laterals of the polysilicon structure.

Preferably, the silicide layer on the polysilicon comprises a barrier, a tungsten layer and a silicon nitride (SiNₓ) layer in sequence.

Preferably, the barrier is titanium nitride.

Preferably, the silicide structure is defined by an anisotropic dry etcher.

Preferably, the protecting layer is formed by chemical vapor deposition (CVD).

Preferably, the protecting layer has a thickness ranged from 50 to 500 A.

Preferably, the protecting layer is silicon nitride (SiNₓ).

Preferably, the protecting structure is defined via an anisotropic dry etcher.

Preferably, the polysilicon structure is defined via an anisotropic dry etcher.

In accordance with an aspect of the present invention, a polycide gate structure is provided. The gate structure includes a polysilicon structure formed upon the substrate and having laterals, an insulating structure disposed on the laterals of the polysilicon structure for insulating the polysilicon structure, a silicide structure formed upon the polysilicon structure and having laterals, and a protecting structure disposed on the laterals of the silicide structure of protecting the silicide structure.

Preferably, the insulating layer is silicon dioxide (SiO₂).

Preferably, the silicide layer upon the polysilicone layer includes a barrier, a tungsten layer and a silicon nitride (SiNₓ) layer in sequence.

Preferably, the barrier is titanium nitride (TiN).

Preferably, the protecting layer is formed by means of chemical vapor deposition (CVD).

Preferably, the protecting layer has a thickness ranged from 50 to 500 A.

Preferably, the protecting layer is silicon nitride (SiNₓ).

Preferably, the polysilicide structure is defined via an anisotropic dry etcher.

Preferably, the insulating structure is formed by means of a dry oxidation method.

Preferably, the polycide structure is defined via anisotropic dry etcher.

Preferably, the protecting structure is defined via an anisotropic dry etcher.

Another aspect, character and executive adduction of the present invention will become more completely comprehensible by the following revelation and accompanying claim.

### BRIEF DESCRIPTION OF THE DRAWINGS

FIG. 1 shows a schematic diagram of the polycide gate structure according to prior arts; and

FIGS. 2(a) to (h) show the schematic diagrams of polycide gate structure according to a preferred embodiment of the present invention.

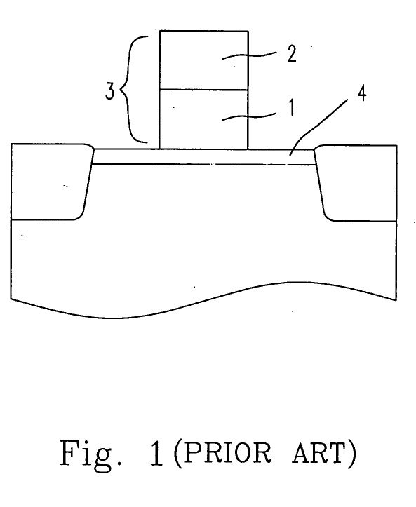

### DETAILED DESCRIPTION OF THE PREFERRED EMBODIMENT

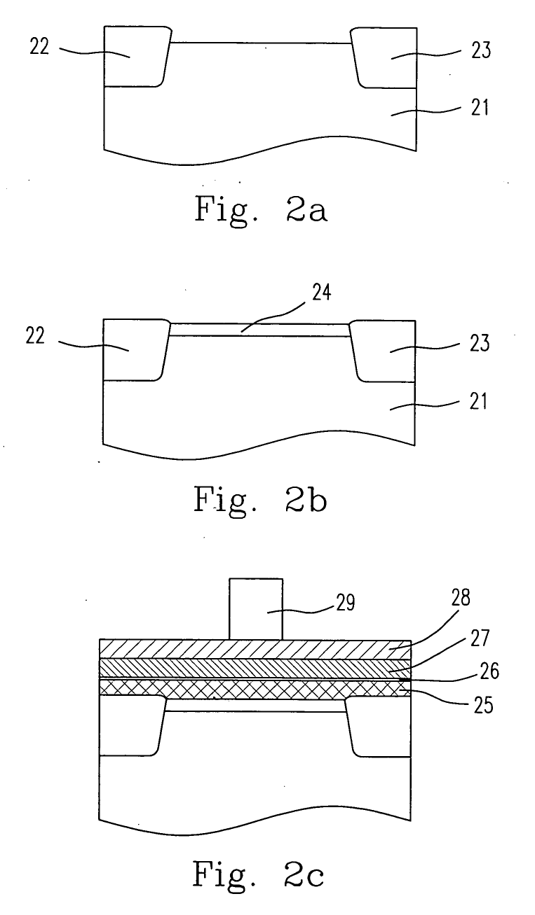

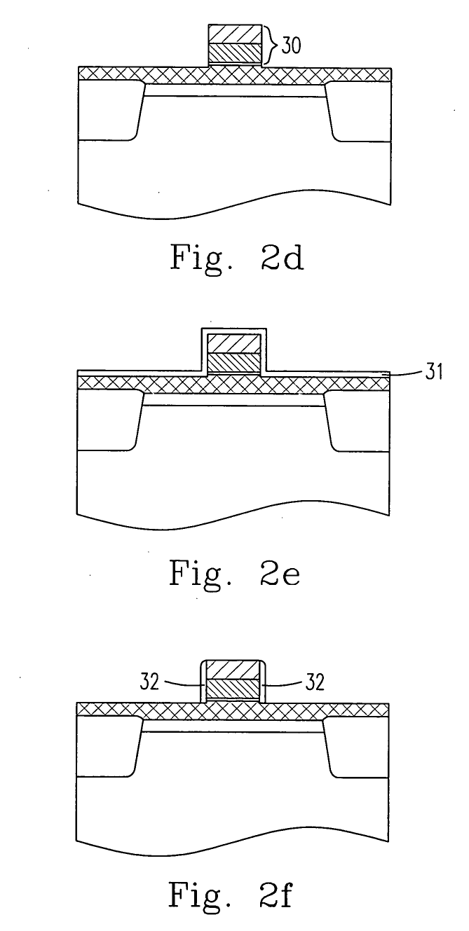

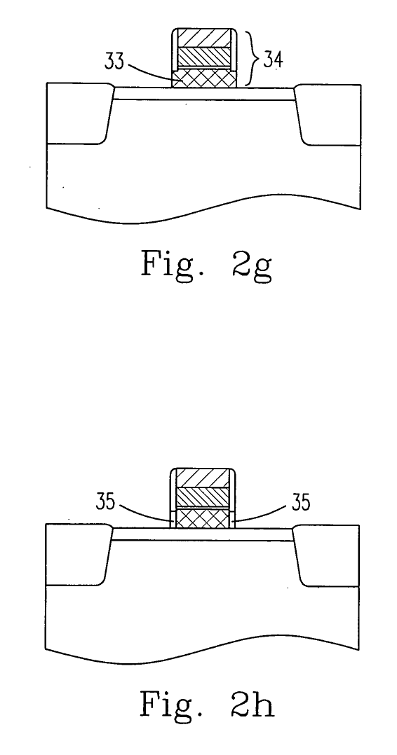

The present invention provides a polycide gate structure and a manufacturing method thereof. Please refer to FIGS. 2(a) to (h) showing the schematic diagrams of polycide gate structure according to a preferred embodiment of the present invention. The detail steps of the manufacturing method are described as follows:

At first, a substrate 21 is provides. A shallow trench isolation method (STI) is used to form a first isolation structure 22 and a second isolation structure 23 upon the substrate 21 separately (as shown in FIG. 2(a)). It could use a localized oxidation isolation method (LOCOS) for forming the isolation structure described above.

A dry oxidation is used to oxidize the silicon on the active region surface for forming a silicon dioxide (SiO₂) layer 24. The silicon dioxide (SiO₂) layer 24 will be the gate oxidation layer of the transistor (as shown in FIG. 2(b)). Then, a polysilicon layer 25 (having a thickness ranged from 500 to 1500 A), a barrier 26 (having a thickness ranged from 50 to 200 A and the material thereof being titanium nitride (TiN)), a tungsten layer 27 (having a thickness ranged from 500 to 2000 A) and a first silicon nitride (SiNₓ) layer 28 (having a thickness ranged from 500 to 3000 A) are formed in sequence via chemical vapor deposition (CVD). A photoresist layer 29 (as shown in FIG. 2 (c)) is covered upon the first silicon nitride layer 28 (SiNₓ). The first silicon nitride (SiNₓ) layer, the tungsten layer and the barrier without protection by the photoresit are removed via an anisotropic dry etcher. Therefore, a silicide structure 30 is defined as shown in FIG. 2(d). A second silicone nitride (SiNₓ) layer 31 is formed upon the polysilicon layer 25 and covers the suicide structure 30 (as shown in FIG. 2(e)) via chemical vapor deposition (CVD). A contact crosspiece between the second silicon nitride (SiNₓ) layer 31 and the polysilicon layer 25 is removed via an anisotropic dry etcher. Besides, a contact crosspiece between the second silicon nitride (SiNₓ) layer 31 and the silicide structure 30 is also removed via an anisotropic dry etcher. A protecting structure 32 (as shown in FIG. 2(f)) is formed after two crosspieces being removed. The first silicon nitride (SiNₓ) layer 28 is used as a mask and the polysilicon layer 25 without protection by the mask on the chip is removed via an anisotropic dry etcher for defining a polysilicon structure 33. The silicide structure 30 and the polysilicon structure 33 could be the polycide gate 34 (as shown in FIG. 2(g)) of the metal oxide semiconductor (MOS). Finally, a dry oxidation method is used to form an insulating structure 35 (as shown in FIG. 2(h)) on laterals of the polysilicon structure 33. The material of insulating layer is silicon dioxide (SiO₂) for isolating the polycide gate structure 33 and the source/drain of metal oxide semiconductor (MOS), and proceeding the following source/drain heavy doping process.

In conclusion, the present invention compared to the traditional manufacturing method could resolve the problem of the pollutant oxide produced by the tungsten layer at high temperature and conforms to industrial environmental consciousness. Furthermore, because the present invention prevents the production of tungsten oxide pollutant it could avoid the leakage current by the contact of tungsten oxide pollutant and silicon layer. Because of the reasons described above, the present invention provides the substantially preferred aids for industrial development.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1-21. (canceled)

22. A polycide gate structure, comprising:
(1) a polysilicon structure formed upon a substrate and having laterals;
(2) an insulating structure disposed on said laterals of said polysilicon structure for insulating said polysilicon structure;
(3) a silicide structure formed upon said polysilicon structure and having laterals; and
(4) a protecting structure formed by means of chemical vapor deposition (CVD) on said laterals of said silicide structure for protecting said silicide structure.

23. The structure as claimed in claim 22, wherein said insulating structure is silicon dioxide (SiO2).

24. The structure as claimed in claim 22, wherein said silicide structure upon said polysilicon structure comprises a barrier, a tungsten layer and a silicon nitride (SiNX) layer in sequence.

25. The structure as claimed in claim 24, wherein said barrier is titanium nitride (TiN).

26. (canceled)

27. The structure as claimed in claim 22, wherein said protecting structure has a thickness ranged from 50 to 500 A.

28. The structure as claimed in claim 22, wherein said protecting structure is silicon nitride (SiNX).

29. The structure method as claimed in claim 22, wherein said polysilicon structure is defined via an anisotropic dry etcher.

30. The structure as claimed in claim 22, wherein said insulating structure is formed by means of a dry oxidation method.

31. The structure as claimed in claim 22, wherein said silicide structure is defined via anisotropic dry etcher.

32. The structure as claimed in claim 22, wherein said protecting structure is defined via an anisotropic dry etcher.
